(19) United States
(12) Patent Application Publication
(10) Pub. No.: US 2015/0076547 A1
(43) Pub. Date: Mar. 19, 2015

(54) Group III Nitride Semiconductor Light-Emitting Device

(71) Applicant: Toyoda Gosei Co., Ltd., Kiyosu-shi (JP)

(72) Inventors: Shingo Totani, Kiyosu-shi (JP); Takashi Kawai, Kiyosu-shi (JP)

(21) Appl. No.: 14/459,217

(22) Filed: Aug. 13, 2014

(30) Foreign Application Priority Data
Sep. 17, 2013 (JP) 2013-192262

(51) Int. Cl. H01L 33/14; H01L 33/46; H01L 33/62; H01L 33/32; H01L 33/42

(52) U.S. Cl. CPC H01L 33/145; H01L 33/32; H01L 33/42; H01L 33/62; H01L 33/46
USPC 257/98

(57) ABSTRACT

The present invention provides a Group III nitride semiconductor light-emitting device exhibiting improved emission performance. A p-electrode comprises a wire bonding portion being connected to a wire, a wiring portion extending in a wiring pattern from the wire bonding portion, and a contact portion being connected to the wiring portion and being in contact with a transparent electrode via holes. A current blocking layer is provided in a specific region between a p-type layer and a transparent electrode. The current blocking layer is formed of an insulating and transparent material with a refractive index lower than that of the p-type layer. Specific region is a region including the contact portion in plan view. The current blocking layer is not provided in regions overlapping with the wire bonding portion and the wiring portion. The current blocking layer is larger by 0 μm to 9 μm in width than the contact portion.

### BACKGROUND OF THE INVENTION

1. Field of the Invention

The present invention relates to a Group III nitride semiconductor light-emitting device exhibiting improved emission performance, particularly to a light-emitting device exhibiting improved emission performance by providing a current blocking layer on a p-type layer.

2. Background Art

A technique is known in which absorption of light by a p-electrode is prevented by preventing light emission from a light-emitting layer at a position overlapping with the p-electrode in plan view, thereby improving emission performance in a Group III nitride semiconductor light-emitting device.

Japanese Patent Application Laid-Open (kokai) No. 2008-192710 discloses a Group III nitride semiconductor light-emitting device exhibiting improved emission performance by forming a transparent insulating film on a p-type layer directly below a pad to prevent that region from emitting light and by reflecting light at an interface between the p-type layer and the insulating film.

Japanese Patent Application Laid-Open (kokai) No. 2013-48199 describes that a current blocking layer is formed directly below a connecting portion of a p-side metal electrode (a portion to be wire bonded of the p-electrode). This is to suppress shielding and absorption of light by the connecting portion of the p-side metal electrode by preventing light emission from an active layer directly below the p-side metal electrode, and to thereby improve emission performance.

Japanese Patent Application Laid-Open (kokai) No. 2009-43934 discloses a Group III nitride semiconductor light-emitting device having a structure in which a transparent electrode, a pad electrode, and an insulating film are sequentially formed on a p-type layer, a p-electrode is provided on the insulating film, the p-electrode is connected to the pad electrode via holes provided in the insulating film, and a reflective film is provided in the insulating film.

In the Group III nitride semiconductor light-emitting device having a structure as disclosed in Japanese Patent Application Laid-Open (kokai) No. 2009-43934, it is arbitrary where the current blocking layer described in Japanese Patent Application Laid-Open (kokai) Nos. 2008-192710 and 2013-48199 is formed. According to the study of the present inventors, it was found that emission performance is reduced depending on the position of the current blocking layer.

### SUMMARY OF THE INVENTION

In view of the foregoing, an object of the present invention is to further improve emission performance in a Group III nitride semiconductor light-emitting device having a structure in which a transparent electrode and an insulating film are sequentially formed on a p-type layer, a p-electrode is formed on the insulating film, and the transparent electrode is connected to the p-electrode via holes provided in the insulating film.

The present invention provides a Group III nitride semiconductor light-emitting device having a transparent electrode, an insulating film, and a p-electrode in this order on a p-type layer formed of Group III nitride semiconductor, the transparent electrode being electrically connected to the p-electrode via holes provided in the insulating film, wherein:

the p-electrode comprises a connecting portion being electrically connected to the outside of the device, a wiring portion extending from the connecting portion, and a contact portion connected to the wiring portion and in contact with the transparent electrode via holes; and

a current blocking layer made of an insulating and transparent material with a refractive index lower than that of the p-type layer is formed between the p-type layer and the transparent electrode. The current blocking layer is provided not in a region overlapping with the wiring portion but in a region including an orthogonal projection of the contact portion in plan view, the current blocking layer is larger by 0 μm to 9 μm in width than the contact portion.

The current blocking layer is preferably provided only in a region including the orthogonal projection of the contact portion in plan view. When the current blocking layer is provided in a region overlapping with the connecting portion in plan view, it hardly affects emission performance. Therefore, it is better and advantageous not to provide the current blocking layer in such a region in terms of production easiness. Moreover, when the current blocking layer is provided in a region overlapping with the wiring portion, the emission performance is reduced.

The current blocking layer is larger by 0 μm to 9 μm in width than the contact portion means that there is a distance between the outer circumference of the contact portion and the outer circumference of the current blocking layer in a direction orthogonal to the outer circumference of the contact portion in plan view. When this distance is not constant, it means an average value. More preferably, the distance is 3 μm to 9 μm, and further preferably, 6 μm to 9 μm.

The current blocking layer preferably has a thickness satisfying the relation of d>λ/(4n) (d: thickness of current blocking layer, n: refractive index of current blocking layer, λ: emission wavelength), and less than 1,500 nm. When the thickness is λ/(4n) or less, light is not sufficiently blocked. When the thickness is 1,500 nm or more, a production problem such as disconnection of p-electrode or transparent electrode and wire occurs due to step. More preferably, the thickness satisfies a range of 100 nm to 800 nm, and further preferably, 100 nm to 500 nm.

The side surface of the current blocking layer may be inclined or orthogonal to the main surface of the p-type layer, but preferably inclined. That is, the current blocking layer has a trapezoid (tapered) cross section the upper base of which is smaller than the lower base. When the side surface is inclined, disconnection of p-electrode or transparent electrode and wire can be prevented. The inclination angle is preferably 5° to 60°, and more preferably 5° to 30°.

The current blocking layer may have any planar shape (shape in plan view) such as circle and square. It is preferably similar to the planar shape of the contact portion because the similar planar shape brings out the function of the current blocking layer evenly in a planar direction.

The current blocking layer may be formed of an insulating and transparent material with a refractive index lower than that of the p-type layer. The transparency is proportional to the emission wavelength. When the p-type layer has a plurality of layers, it may have a refractive index lower than that of a layer most proximal to the current blocking layer. The p-type layer may be formed of, for example, SiO₂, SiN, SiON, Al₂O₃, TiO₂, ZrO₂, HfO₂, Nb₂O₅, and MgF₂.

A reflective film may be provided in a region overlapping with the p-electrode of the insulating film in plan view. The reflective film may be a single-layer film or a multi-layer film formed of a high reflectance metal such as Al, Ag, Al alloy, and Ag alloy. Moreover, the wiring portion may be formed of a high reflectance metal.

The current blocking layer and the reflective film in the insulating film may be a dielectric multi-layer film. The dielectric multi-layer film has a structure in which a low refractive index material and a high refractive index material are alternately and repeatedly deposited, and each optical film thickness is designed to be ¼ of the emission wavelength.

The light-emitting device of the present invention may be either a face-up type or a flip-chip type.

In the Group III nitride semiconductor light-emitting device of the present invention, the current blocking layer prevents light emission from the light-emitting layer directly below the p-type contact portion and reduces the light directed toward the p-type contact portion by reflecting light by the current blocking layer, thereby improving the emission performance.

In the Group III nitride semiconductor light-emitting device of the present invention, the current blocking layer is formed in regions including the orthogonal projections of the contact portions in a plan view. Therefore, the light avoiding the current blocking layer from a diagonal direction and being directed toward the contact portions of the p-electrode is reduced, thereby suppressing the light emitted from the light-emitting layer below the contact portions. Moreover, the light being directed toward the contact portion is reduced by reflecting light at an interface between the p-type layer and the current blocking layer. As a result, the emission performance can be further improved.

### BRIEF DESCRIPTION OF THE DRAWINGS

Various other objects, features, and many of the attendant advantages of the present invention will be readily appreciated as the same becomes better understood with reference to the following detailed description of the preferred embodiments when considered in connection with the accompanying drawings, in which:

FIG. 1 is a cross-sectional view of the structure of a Group III nitride semiconductor light-emitting device according to Embodiment 1;

FIG. 2 is a top plan view of the Group III nitride semiconductor light-emitting device according to Embodiment 1;

FIG. 3 is a graph of the emission performance when a current blocking layer is formed only under a contact portion 16c;

FIG. 4 is a graph of the emission performance when a current blocking layer is formed only under a wiring portion 16b;

FIG. 5 is a graph of the emission performance when a current blocking layer is formed only under a wire bonding portion 16a;

FIG. 6 is a cross-sectional view of the structure of a Group III nitride semiconductor light-emitting device according to Embodiment 2;

FIG. 7 is a cross-sectional view of the structure of a Group III nitride semiconductor light-emitting device according to variation;

FIGS. 8A to 8D are sketches showing processes for producing the Group III nitride semiconductor light-emitting device according to Embodiment 1;

FIG. 9 is a cross-sectional view of the structure of a Group III nitride semiconductor light-emitting device according to Embodiment 3; and

FIG. 10 is a top plan view of the structure of the Group III nitride semiconductor light-emitting device according to Embodiment 3.

### DETAILED DESCRIPTION OF PREFERRED EMBODIMENTS

A specific embodiment of the present invention will next be described with reference to the drawings. However, the present invention is not limited to the embodiment.

### Embodiment 1

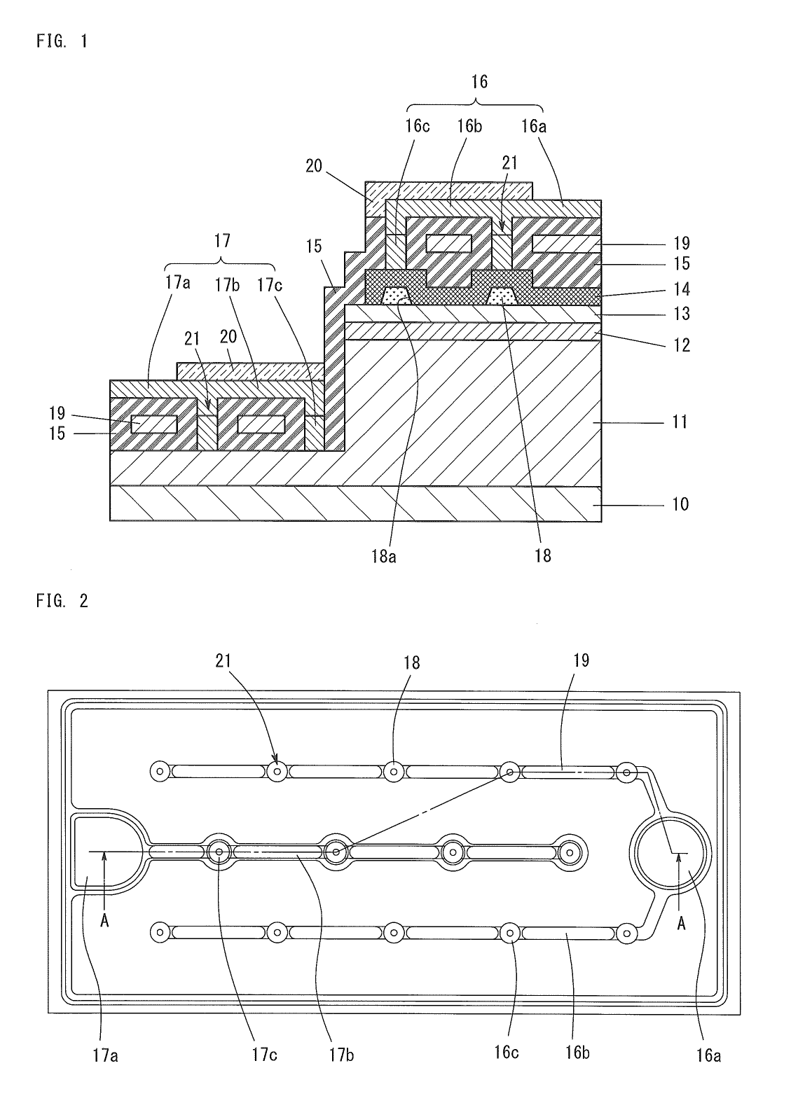

FIG. 1 is a cross-sectional view of the structure of a Group III nitride semiconductor light-emitting device according to Embodiment 1. FIG. 2 is a top plan view of the Group III nitride semiconductor light-emitting device according to Embodiment 1. FIG. 1 is an A-A cross-sectional view of FIG. 2. As shown in FIG. 2, the Group III nitride semiconductor light-emitting device according to Embodiment 1 is of a face-up type having a rectangular shape in plan view.

As shown in FIG. 1, the Group III nitride semiconductor light-emitting device according to Embodiment 1 includes a substrate 10, an n-type layer 11 via a buffer layer (not illustrated) on the substrate 10, a light-emitting layer 12 on the n-type layer 11, and a p-type layer 13 on the light-emitting layer 12. Each of the n-type layer 11, the light-emitting layer 12, and the p-type layer 13 is formed of Group III nitride semiconductor. A groove extending from the surface of the p-type layer 13 to the n-type layer 11 is formed, and the n-type layer 11 is exposed through the bottom surface of the groove. An insulating film 15 is provided so as to continuously cover the transparent electrode 14 on the p-type layer 13, the transparent electrode 14, and the n-type layer 11 exposed through the bottom surface of the groove. A p-electrode 16 and an n-electrode 17 are separately formed on the insulating film 15. Moreover, current blocking layers 18 are provided in specific regions between the p-type layer 13 and the transparent electrode 14. Each structure will be described below in detail.

The substrate 10 is a sapphire substrate having an a-plane main surface on which concaves and convexes (not illustrated) are formed on the n-type layer 11 side. The concaves and convexes are provided for improving emission performance. The substrate 10 may be formed of any material on which Group III nitride semiconductor crystal can grow, for example, SiC, Si, and ZnO other than sapphire.

The n-type layer 11 has a structure in which an n-type contact layer, an n-type ESD layer, and an n-type SL layer are sequentially deposited on the substrate 10. The n-type contact layer is in contact with the n-electrode 17. The n-type contact layer is formed of n-GaN having a Si concentration of 1×10¹⁸/cm³ or more. When the n-type contact layer comprises a plurality of layers with different carrier concentrations, contact resistance can be reduced in the n-electrode 17. The n-type ESD layer serves as an electrostatic-breakdown-voltage-improving layer for preventing electrostatic breakdown of the device. The n-type ESD layer has a layered structure including an undoped GaN layer and a Si-doped n-GaN layer. The n-type SL layer is an n-type superlattice layer having a superlattice structure in which layer units are repeatedly deposited, each unit including an InGaN layer, a GaN layer, and an n-GaN layer. The n-type SL layer serves as a strain relaxation layer for relaxing stress applied to the light-emitting layer 12.

The light-emitting layer 12 has a MQW structure in which an InGaN well layer and an AlGaN barrier layer are repeatedly deposited. A protection layer may be provided between the well layer and the barrier layer for preventing In evaporation.

The p-type layer 13 has a structure in which a p-type cladding layer and a p-type contact layer are sequentially deposited on the light-emitting layer 12. The p-type cladding layer is provided for preventing diffusion of electrons to the p-type contact layer. The p-type cladding layer is formed by repeatedly depositing layer units, each layer unit including a p-InGaN layer and a p-AlGaN layer. The p-type contact layer is provided for achieving good contact between the p-electrode 16 and the p-type layer 13. The p-type contact layer is formed of p-GaN having a Mg concentration of 1×10¹⁹/cm³ to 1×10²²/cm³ and a thickness of 100 Å to 1,000 Å.

The structure of the n-type layer 11, the light-emitting layer 12, and the p-type layer 13 is not limited to the above, any structure which is conventionally used in the Group III nitride semiconductor light-emitting device may be employed.

The transparent electrode 14 may be formed of electrically conductive oxide such as ITO (indium tin oxide), IZO (indium zinc oxide), and ICO (indium cerium oxide). The transparent electrode 14 is formed so as to continuously cover the p-type layer 13 and the current blocking layers 18. Therefore, the transparent electrode 14 is formed in a wavy film along the tops of the current blocking layers 18. Concaves and convexes may be provided on the surface of the transparent electrode 14 to improve light extraction efficiency.

The insulating film 15 is formed so as to continuously cover the n-type layer 11 exposed on the bottom surface of the groove and the transparent electrode 14. The insulating film 15 is formed of SiO₂, and may be formed of SiN, Al₂O₃, TiO₂ other than SiO₂. Holes 21 are provided in specific regions of the insulating film 15, and pass through the insulating film 15. The holes 21 are filled with the wiring portions 16b of the p-electrode 16 described later.

Reflective films 19 are provided in regions overlapping in plan view with the p-electrode 16 and the n-electrode 17 of the insulating film 15. The reflective films 19 are enclosed with the insulating film 15 and thus are electrically insulated, thereby metal migration is prevented. The reflective films 19 are provided to suppress absorption of light by the p-electrode 16 and the n-electrode 17 by reflecting light directed toward the p-electrode 16 and the n-electrode 17, and to thereby improve emission performance.

Each of the reflective films 19 is formed of a material with a reflectance higher than that of the p-electrode 16 or the n-electrode 17, such as Al, Ag, an Al alloy, or an Ag alloy. The reflective film 19 may be a single-layer film or a multi-layer film. When the reflective film 19 is a multi-layer film, the film may be formed of, for example, Al alloy/Ti, Ag alloy/Al, Ag alloy/Ti, Al/Ag/Al, or Ag alloy/Ni. Hereinafter, the symbol “/” refers to a layered structure; for example, “A/B” refers to a layered structure in which layer B is formed after formation of layer A. The symbol “/” is used in a similar meaning in the description of material. In order to improve adhesion of the reflective film 19 to the insulating film 15, a thin film formed of, for example, Ti, Cr, or Al may be provided between the reflective film 19 and the insulating film 15.

The reflective film 19 may be formed of a dielectric multi-layer film. The dielectric multi-layer film is a multi-layer film formed of a plurality of alternately deposited pairs of films, each pair including a film formed of a material of low refractive index and a film formed of a material of high refractive index, wherein the thickness of each film is designed to be ¼ emission wavelength. The material of low refractive index may be, for example, SiO₂ or MgF₂, and the material of high refractive index may be, for example, SiN, TiO₂, ZrO₂, Ta₂O₅, or Nb₂O₅. From the viewpoint of improvement of the reflectance of the dielectric multi-layer film, preferably, a large difference in refractive index is provided between the material of low refractive index and the material of high refractive index. The dielectric multi-layer film is preferably formed of a large number of pairs of films. The number of pairs of films is preferably 5 or more. However, the number of pairs of films is preferably 30 or less so as not to increase the overall thickness of the dielectric multi-layer film increases and cause problems in production processes.

The p-electrode 16 comprises a wire bonding portion 16a (the connecting portion of the present invention), a wiring portion 16b, and a contact portion 16c. The contact portion 16c is formed of Ni/Au/Al, the wire bonding portion 16a and the wiring portion 16b are formed of Ti/Au/Al.

The wire bonding portion 16a is a circular region located on the insulating film 15, to which a bonding wire is connected. The wiring portion 16b is a linear portion extending from the wire bonding portion 16a, which is located on the insulating film 15a. By having such a linear structure, current is diffused in a direction parallel to the main surface of the device. The wiring portion 16b is also formed inside the holes 21 provided in the insulating film 15. The contact portions 16c are a plurality of dotted circular regions provided on the transparent electrode 14. The contact portions 16c are connected to the wiring portion 16b via holes 21 provided in the insulating film 15. The contact portions 16c are provided for achieving good contact between the p-electrode 16 and the transparent electrode 14. The holes 21 and the contact portions 16c do not necessarily have the same shape in plan view as long as the holes 21 have a shape to be contained in the contact portions 16c.

As shown in FIG. 2, the wire bonding portion 16a is disposed in the vicinity of the center of one shorter side of the rectangle. Two linear wiring portions 16b extend from the wire bonding portion 16a. The wiring portions 16b comprise a linear portion extending along one longer side in the vicinity of one longer side, and a linear portion extending along the other longer side in the vicinity of the other longer side. Each of the linear portions is divided in a direction perpendicular to the main surface of the device by the holes 21, and connected to the circular contact portions 16c at the dividing ends.

The current blocking layers 18 are provided for preventing light emission from regions overlapping in plan view with the current blocking layers 18 of the light-emitting layer 12 by blocking the current in that region. Moreover, light directed toward the tops of the current blocking layers 18 is reduced by reflection or refraction at the interfaces between the p-type layer 13 and the current blocking layers 18. Through these two effects, absorption and shielding of light by the p-electrode 16 located at the tops of the current blocking layers 18 are suppressed, thereby improving emission performance.

The current blocking layers 18 are located in regions including the orthogonal projections of the contact portions 16c in plan view as shown in FIG. 1. As shown in FIG. 2, the current blocking layers 18 are circles concentric with each of the contact portions 16c in plan view. In other part of the p-electrode 16, i.e., in regions overlapping with the wire bonding portion 16a and the wiring portions 16b, current blocking layers 18 are not formed. The reason for not forming a current blocking layer 18 in a region overlapping with the wire bonding portion 16a is that even if the current blocking layer 18 is formed in this region, the emission performance is only slightly improved. Moreover, the current blocking layer is preferably not formed in terms of production easiness and production cost. The reason for not forming current blocking layers 18 in regions overlapping with the wiring portions 16b is that the emission performance is, on the contrary, reduced by forming the current blocking layers 18 in these regions.

Each of the contact portions 16c and the current blocking layers 18 has a planar circle shape, and each of the contact portions 16c has a diameter of 16 μm. Although the contact portions 16c and the current blocking layers have a similar shape, the planar shapes of the current blocking layers 18 are not necessarily similar to those of the contact portions 16c. However, when they are similar, the function of the current blocking layers 18 can be evenly performed in a planar direction.

The current blocking layer 18 may be formed of any insulating and transparent material with a refractive index lower than that of the p-type layer 13, other than SiO₂. When the p-type layer 13 comprises a plurality of layers, the refractive index of the current blocking layer 18 may be lower than that of a layer most proximal to the current blocking layer 18. When the p-type layer 13 has a structure in which a p-type cladding layer and a p-type contact layer are sequentially deposited, the current blocking layer 18 may be formed of any material with a refractive index lower than that of the p-type contact layer. For example, metal oxide, metal nitride, metal oxynitride, specifically, SiO₂, SiN, SiON, Al₂O₃, TiO₂, ZrO₂, HfO₂, Nb₂O₅, and MgF₂ may be used. The current blocking layer 18 may be a single layer or a multilayer formed of such materials or a dielectric multi-layer film formed of a plurality of alternately deposited two types of films with different refractive indices, wherein the optical film thickness of each film is 4/1 wavelength. When such a dielectric multi-layer film is employed, the reflectance is improved, and thus light directed toward the p-electrode is reduced and absorption of light by the p-electrode is reduced, thereby improving emission performance.

The planar shape of the current blocking layer 18 is larger by 0 μm to 9 μm in width than that of the contact portion 16c. Here, “width” means a distance from the outer circumference of the contact portion 16c to the outer circumference of the current blocking layer 18 in a direction orthogonal to the outer circumference of the contact portion 16c in plan view. When the width is not constant, the average width may be 0 μm to 9 μm. In Embodiment 1, the contact portion 16c and the current blocking layer 18 are both circles, and the width means the difference in radius. Therefore, the term “width difference” is used hereinafter to avoid confusion. When the width difference is less than 0 μm (i.e., the area of the current blocking layer 18 is smaller than that of the contact portion 16c), the emission performance is not sufficiently improved, which is not preferable. When the width difference is larger than 9 μm, light is not emitted from larger region by the current blocking layer 18, and the emission performance is reduced, which is not preferable. More preferably, the width difference is 3 μm to 9 μm, and further preferably, 6 μm to 9 μm.

The side surface 18a of the current blocking layer 18 is inclined by 5° to 60° to the main surface of the p-type layer 13. That is, the current blocking layer 18 has a trapezoid (tapered) shape in a cross section of the device. Such a shape prevents disconnection of the transparent electrode 14, the p-electrode 16, and the wire. More preferably, the inclination angle is 5° to 30°.

The thickness of the current blocking layer 18 is preferably larger than λ/(4n) (λ: emission wavelength, n: refractive index of current blocking layer 18). Sufficient insulation and reflecting function can be obtained by having a thickness larger than λ/(4n). More preferably, the thickness is 100 nm or more. The thickness of the current blocking layer 18 is preferably less than 1,500 nm. This is because when the thickness is larger than this, it may lead to a problem such as disconnection of the wire or the transparent electrode 14 and the p-electrode 15 due to step caused by the thickness. More preferably, the thickness is 500 nm or less.

The n-electrode 17 comprises a wire bonding portion 17a, a wiring portion 17b, and a contact portion 17c in the same as the p-electrode 16, and each of them serves in the same as the p-electrode 16. As shown in FIG. 2, the wire bonding portion 17a is located in the vicinity of the center of the end side opposite to the wire bonding portion 16a. One linear wiring portion 17b extends along the longer side from the wire bonding portion 17a, and is disposed between two linear wiring portions 16b. The wire bonding portion 17a and the wiring portion 17b of the n-electrode 17 are formed of the same materials as those of the wire bonding portion 16a and the wiring portion 16b of the p-electrode 16. The contact portion 17c is formed of the same materials as those of the contact portion 16c.

In a region except for the wire bonding portion 16a of the p-electrode 16 and a region except for the wire bonding portion 17a of the n-electrode 17, a protective film 20 is formed to prevent current short circuit.

As described above, in the Group III nitride semiconductor light-emitting device according to Embodiment 1, the current blocking layers 18 are provided in regions including the orthogonal projections of the contact portions 16c in plan view, and each of them is larger by 0 μm to 9 μm in width than each of the contact portion 16c. Thus, there are the following three advantages.

The first advantage is that since each of the current blocking layer 18 is larger by 0 μm to 9 μm in width than each of the contact portion 16c, light avoiding the current blocking layer 18 and being directed toward the contact portion 16c from an oblique direction is reduced, thereby improving emission performance.

The second advantage is that since the current blocking layers 18 are not provided in regions overlapping with the wire bonding portion 16a and the wiring portions 16b, the emission performance is not impaired.

The third advantage is that even in a region where the reflective film 19 cannot be provided, absorption of light by the p-electrode 16 can be suppressed by the current blocking layer 18. The contact portions 16c are provided to be connected to the wiring portions 16b via the holes 21 in a direction perpendicular to the main surface of the substrate. Therefore, the insulating film 15 cannot be provided between the transparent electrode 14 and the contact portion 16c, and absorption of light by the p-electrode 16 cannot be suppressed by the reflective film 19 in the insulating film 15. However, even in a region where the reflective film 19 cannot be provided, the current blocking layer 18 can be provided. Thus, absorption of light by the contact portion 16c can be suppressed by forming the current blocking layer 18 in such a region (i.e., region overlapping with the contact portion 16c), thereby improving emission performance.

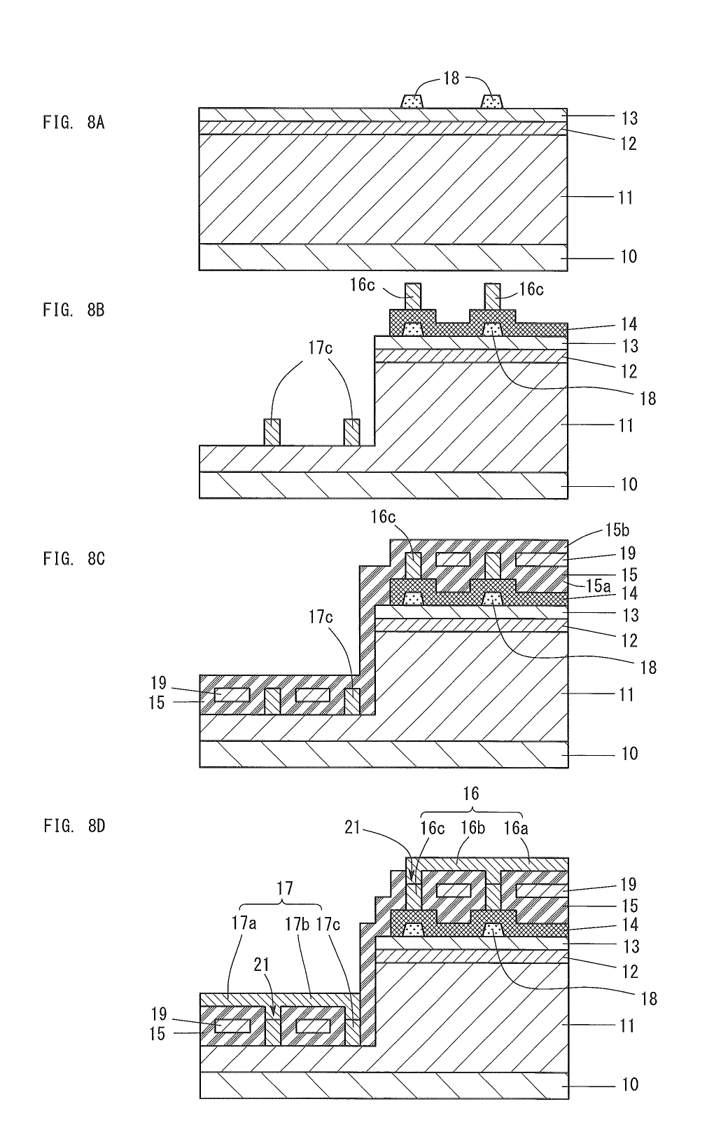

Next will be described processes for producing the Group II nitride semiconductor light-emitting device according to Embodiment 1 with reference to FIG. 8.

Firstly, a sapphire substrate 10 having concaves and convexes thereon was prepared. Thermal cleaning was performed in a hydrogen atmosphere to remove impurities from the surface of the sapphire substrate 10.

Subsequently, an n-type layer 11, a light-emitting layer 12, and a p-type layer 13 were sequentially deposited on the substrate 10 through MOCVD. The gases employed were as follows: TMG (trimethylgallium) as a Ga source; TMA (trimethylaluminum) as an Al source; TMI (trimethylindium) as an In source; ammonia as a nitrogen source; bis-cyclopentadienyl magnesium as a p-type dopant gas; and silane as an n-type dopant gas. Hydrogen or nitrogen was employed as a carrier gas.

Then, current blocking layers 18 were formed on the p-type layer 13. The current blocking layers 18 were patterned by photolithography and wet etching after SiO₂ film was formed by vapor deposition or CVD. They may be patterned by photolithography, sputtering or vapor deposition, and the lift-off process. The current blocking layers 18 were formed only in regions including contact portions 16c of a p-electrode 16 being formed later, on the p-type layer 13. Each of them was formed larger by 0 μm to 9 μm in width than the contact portion 16c (refer to FIG. 8A).

Subsequently, a transparent electrode 14 was formed on specific regions of the p-type layer 13 and the current blocking layers 18. The transparent electrode 14 was patterned by photolithography and wet etching after the formation of an ITO film by sputtering. Thereafter, thermal cleaning was performed at 700° C. for 5 minutes in a nitrogen atmosphere at a reduced-pressure not higher than 10 Pa. The p-type layer 13 was converted, i.e., activated, to the p-type conduction, and the transparent electrode 14 was crystallized, thereby lowering the resistance. Thermal cleaning may be performed at a normal pressure.

Next, a specific portion of the p-type layer 13 was subjected to dry etching, to thereby form a groove so that the n-type layer 11 was exposed through the bottom of the groove. The contact portions 16c of the p-electrode 16 were formed in specific regions on the transparent electrode 14, and the contact portions 17c of the n-electrode 17 were formed in specific regions on the n-type layer 11 exposed through the bottom of the groove (refer to FIG. 8B). The contact portions 16c and 17c were patterned by photolithography, vapor deposition and the lift-off process. The contact portions 16c and 17c may be separately formed. However, when the contact portions 16c and 17c are formed of the same material, the contact portions 16c and 17c may be formed simultaneously. Therefore, production processes can be simplified, and production cost can be reduced. Thereafter, thermal cleaning was performed at 550° C. for five minutes in a reduced-pressure oxygen atmosphere of 25 Pa, and the contact portions 16c and 17c were alloyed.

Subsequently, an insulating film 15 including the reflective film 19 therein was formed so as to cover the entire top surface (FIG. 8C). The insulating film 15 was formed as follows. Firstly, a first insulating film 15a was formed on the entire top surface by CVD. Then, reflective films 19 were formed on specific regions on the first insulating film 15a (corresponding to regions overlapping with the p-electrode 16 and the n-electrode 17 in plan view) by vapor deposition, photolithography, and etching. The reflective films 19 may be formed by the lift-off process. Next, second insulating film 15b was formed on the first insulating film 15a and on the reflective films 19. The first insulating film 15a and the second insulating film 15b together formed an insulating film 15, to thereby form the insulating film 15 including reflective films 19 in specific regions therein.

Subsequently, specific regions of the insulating film 15 (corresponding to the tops of the contact portions 16c and 17c) were subjected to dry etching, to thereby form holes 21 passing through the insulating film 15. The contact portions 16c and 17c were exposed through the bottoms of the holes 21. Then, a wire bonding portion 16a and wiring portions 16b of the p-electrode 16, and a wire bonding portion 17a and wiring portions 17b of the n-electrode 17 were formed on regions of the insulating film 15 corresponding to the tops of the reflective films 19 by photolithography, vapor deposition and the lift-off process. Here, the wiring portions 16b and 17b were formed so as to fill the inside of the holes 21 so that the wiring portions 16b were connected to the contact portions 16c and the wiring portions 17b were connected to the contact portions 17c inside the holes 21 (refer to FIG. 8D).

Thereafter, a protective film 20 was formed on the entire top surface except for the wire bonding portions 16a and 17a by CVD, photolithography, and dry etching. Thus, the Group III nitride semiconductor light-emitting device according to Embodiment 1 was produced.

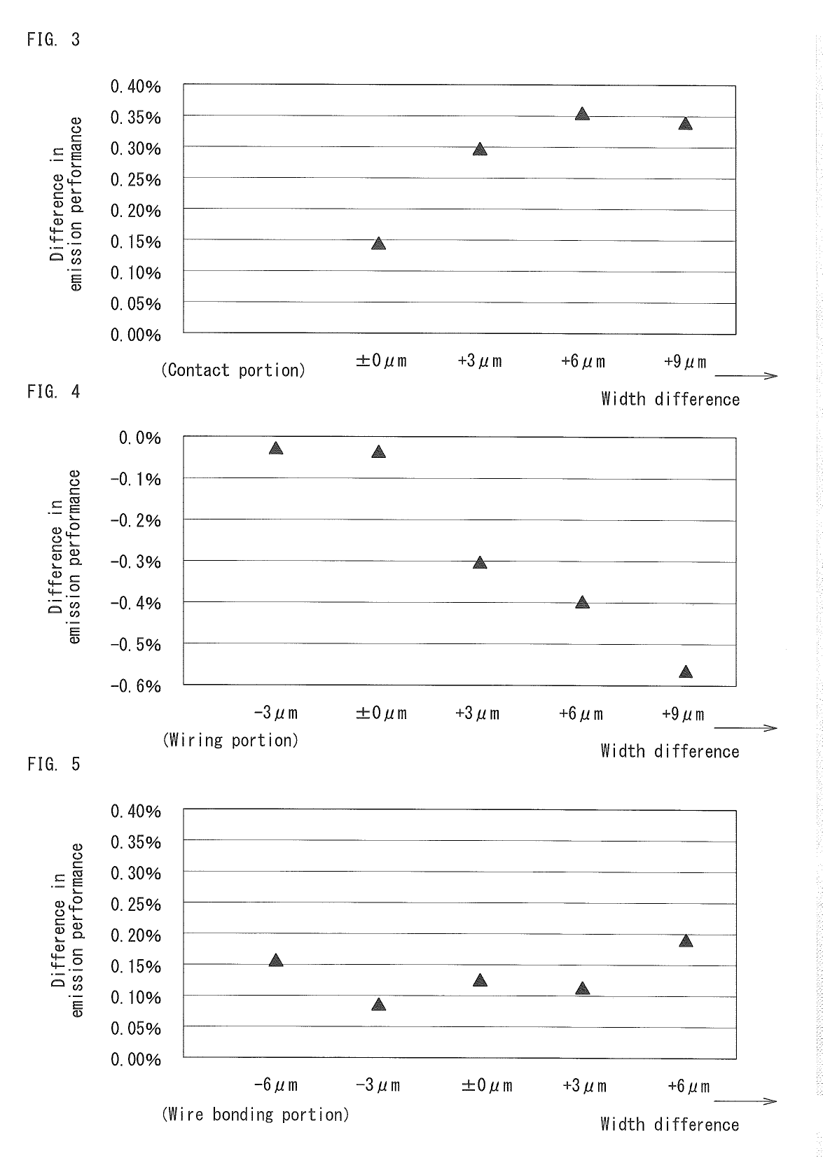

Next will be described the Experimental Examples. FIGS. 3 to 5 show the result of how the emission performance varies depending on positions and width differences of the current blocking layers 18. The difference in emission performance shown on the vertical axes of FIGS. 3 to 5 was obtained from the comparison with the device having no current blocking layer 18. Here, “the difference in emission performance” is defined as the emission performance of the light-emitting device having current blocking layers 18 minus the emission performance of the light-emitting device having no current blocking layer 18. FIG. 3 shows the case when the current blocking layers 18 are provided only in regions overlapping with the contact portions 16c in plan view, FIG. 4 shows the case when the current blocking layers 18 are provided only in regions overlapping with the wiring portions 16b in plan view, and FIG. 5 shows the case when the current blocking layer 18 is provided only in a region overlapping with the wire bonding portion 16a in plan view. The vertical axes of FIGS. 3 to 5 indicate the difference in the emission performance when compared to the case when the current blocking layer 18 is not provided. The horizontal axes indicate the width differences, i.e., the width of the current blocking layer 18 minus the width of the contact portion 16c.

As shown in FIG. 3, when the contact portion 16c and the current blocking layer 18 coincide in shape in plan view (i.e., when the width difference is 0 μm), the emission performance is improved by 0.15% compared with when the current blocking layer 18 is not provided. The larger the current blocking layer 18 than the contact portion 16c, the more the emission performance is improved. When the width difference between the current blocking layer 18 and the contact portion 16c is 6 μm to 9 μm, the emission performance is increased by 0.30%, and almost saturated. When the width difference is 9 μm, the emission performance is slightly reduced than when the width difference is 6 μm. From this, it is considered that even if the current blocking layer 18 is larger by 9 μm in width than the contact portion 16c, the emission performance is not improved, and non-emitting region of the light-emitting layer 12 is enlarged and conversely the emission performance is reduced. It is also considered that contact between the p-type layer 13 and the transparent electrode 14 is impaired. Therefore, it was found that the current blocking layer 18 is preferably larger by 0 μm to 9 μm in width than the contact portion 16c, particularly preferably 3 μm to 9 μm, and further preferably 6 μm to 9 μm.

As shown in FIG. 4, when the wiring portion 16b and the current blocking layer 18 coincide in shape in plan view (when the width difference is 0 μm), and when the current blocking layer 18 is smaller than the wiring portion 16b (when the width difference is −3 μm), the difference in emission performance is almost 0. When the current blocking layer 18 is larger than the wiring portion 16b, the emission performance is reduced. Therefore, it is better not to provide the current blocking layer 18 in a region overlapping with the wiring portion 16b in plan view.

The reason why the emission performance is reduced when the current blocking layer 18 is provided in a region overlapping with the wiring portion 16b in plan view, is as follows. Firstly, since the reflective films 19 and the insulating films 15 are formed directly below the wiring portion 16b, less light from the light-emitting layer 12 is shielded by the wiring portion 16b. Secondly, the non-emitting region is enlarged by the current blocking layer 18. As a result, the deterioration of the emission performance is larger than the effect of reducing light, which is shielded by the wiring portion 16b, by the current blocking layer 18.

As shown in FIG. 5, when the current blocking layer 18 is provided only in the wire bonding portion 16a, even if the width difference between the current blocking layer 18 and the wire bonding portion 16a varies, the difference in emission performance is not significantly changed, and only improved by 0.10% to 0.15%. This is considered as follows: Since the area of the wire bonding portion 16a is large, more light from the light-emitting layer 12 is shielded. The emission performance is improved due to reduction of light shielding by the current blocking layer 18. However, when the width of the current blocking layer 18 is increased, the non-emitting region is enlarged, and thus the effect of improving emission performance is cancelled. Consequently, the emission performance is kept almost constant. Even if the current blocking layer 18 is provided in a region overlapping with the wire bonding portion 16a, the effect of improving emission performance is small. Therefore, the current blocking layer 18 may not be provided in a region overlapping with the wire bonding portion 16a, considering time or production cost. Needless to say, when time or cost is not a problem, the current blocking layer 18 may be provided in the wire bonding portion 16a.

As is clear from the above results in FIGS. 3 to 5, the current blocking layers 18 are formed in regions including the contact portions 16c in plan view so that each of the current blocking layers 18 is larger by 0 μm to 9 in width μm than each of the contact portion 16c. Preferably, the current blocking layers 18 are not formed in regions overlapping with the wire bonding portion 16a and the wiring portions 16b.

### Embodiment 2

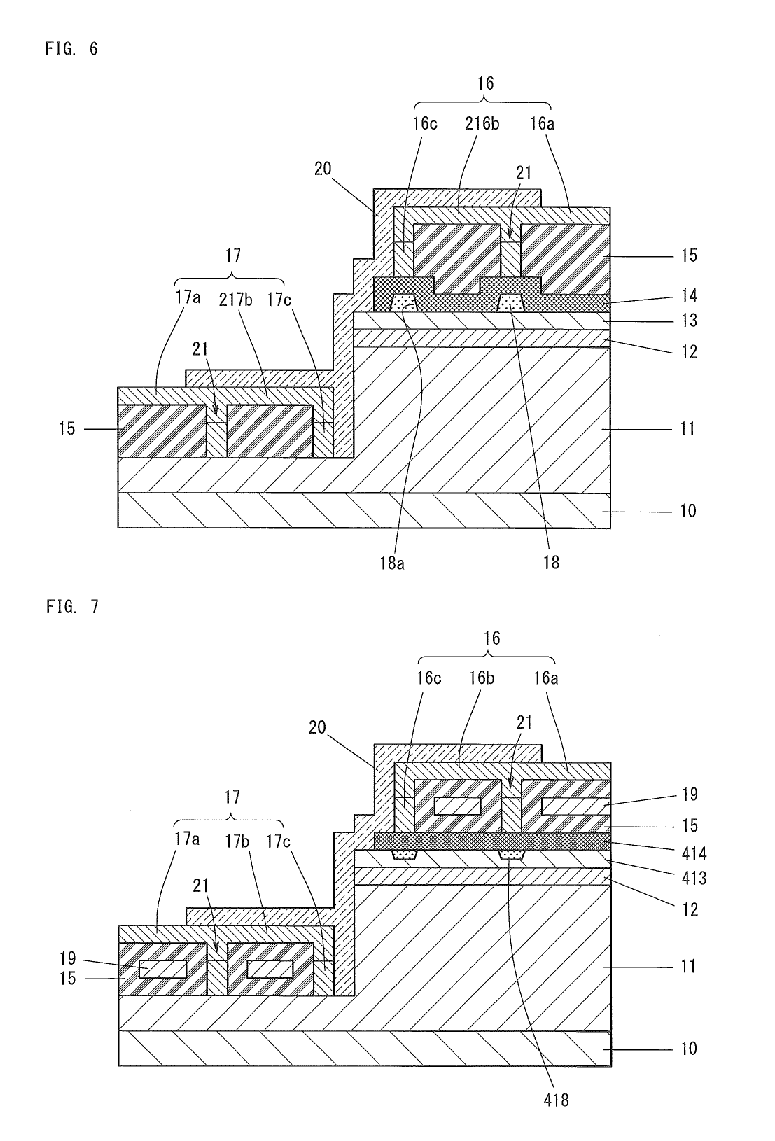

FIG. 6 is a cross-sectional view of the structure of a Group III nitride semiconductor light-emitting device according to Embodiment 2. The Group III nitride semiconductor light-emitting device according to Embodiment 2 has the same structure as the Group III nitride semiconductor light-emitting device according to Embodiment 1, except that the reflective films are omitted in the insulating films 15, the wiring portions 16b and 17b are respectively replaced with the wiring portions 216b and 217b, each of which is formed of a high reflectance metal. A high reflectance metal may be formed of a metal material exhibiting a high reflectance (e.g., 80% or more) for light of emission wavelength of the Group III nitride semiconductor light-emitting device, such as Ag, Al, or Rh. Such use of high reflectance metal as wiring portions 216b and 217b suppresses absorption of light by the wiring portions 216b and 217b and improves light extraction performance of the device.

Similar to the case of Embodiment 1, the Group III nitride semiconductor light-emitting device according to Embodiment 2 also exhibits improved emission performance because the current blocking layers 18 are provided in regions including the contact portions 16c in plan view.

### Embodiment 3

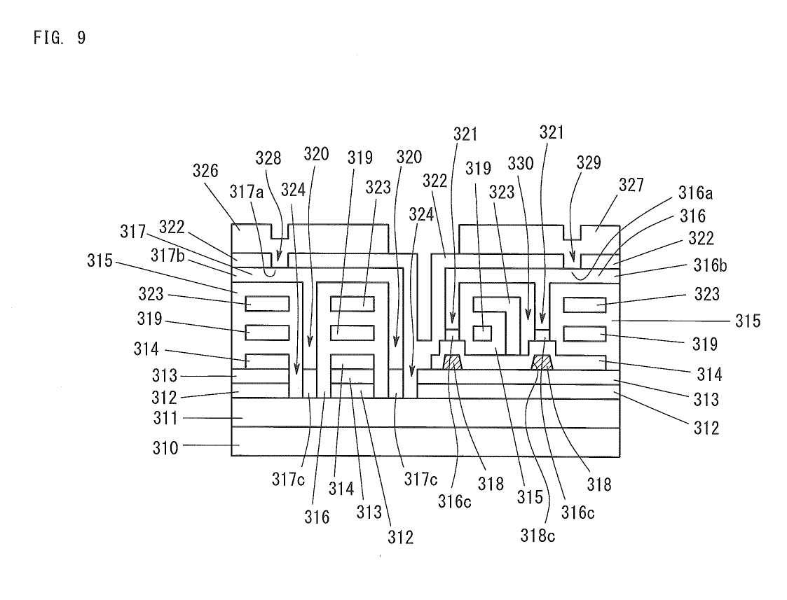

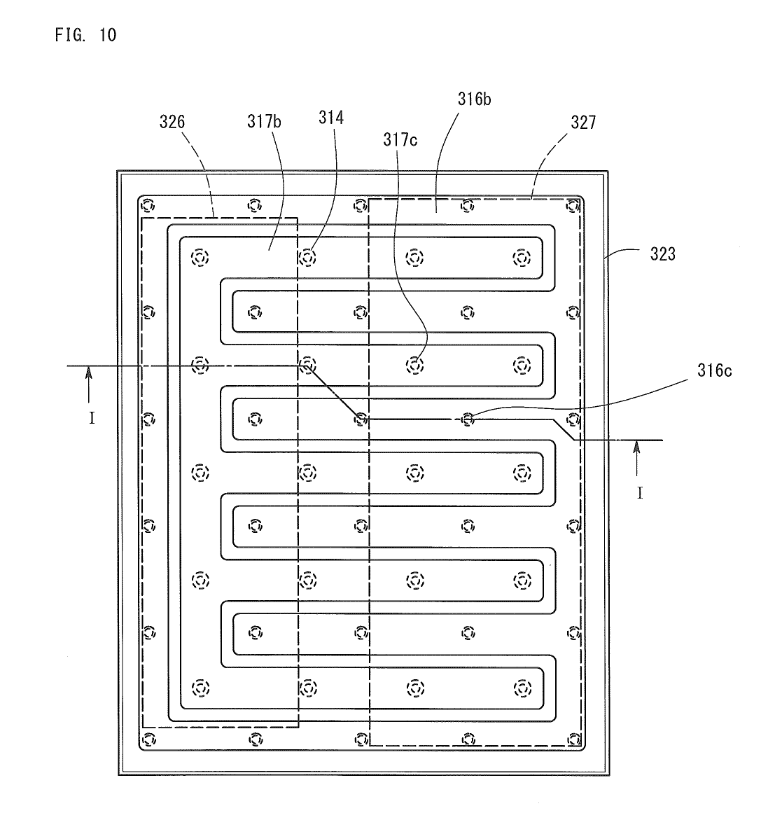

FIG. 9 is a cross-sectional view of the structure of the Group III nitride semiconductor light-emitting device according to Embodiment 3. FIG. 10 is a top plan view of the structure of the Group III nitride semiconductor light-emitting device according to Embodiment 3. FIG. 9 is a I-I cross-sectional view of FIG. 10. As shown in FIGS. 9 and 10, the Group III nitride semiconductor light-emitting device according to Embodiment 3 is a rectangular flip-chip-type device in plan view.

As shown in FIG. 9, the Group III nitride semiconductor light-emitting device according to Embodiment 3 includes a substrate 310; an n-type layer 311, a light-emitting layer 312, and a p-type layer 313 which are sequentially deposited on the sapphire substrate 310 via a buffer layer (not illustrated), and each of which is formed of a Group III nitride semiconductor. On the surface of the p-type layer 313, there are provided holes 324 having a depth extending from the top surface of the p-type layer 313 to the n-type layer 311. ITO transparent electrodes 314 are provided on almost entire surface other than regions having holes 324 of the p-type layer 313. Current blocking layers 318 are provided in specific regions between the p-type layers 313 and the transparent electrodes 314. Moreover, an insulating film 315 is provided so as to continuously cover the surface of the transparent electrodes 314, the side surfaces and bottom surfaces of holes 324. A p-electrode 316 and an n-electrode 317 are separately formed on the insulating film 315.

The Group III nitride semiconductor light-emitting device according to Embodiment 3 is of a flip-chip type, in which reflective films 319 are enclosed with the insulating film 315, and light is extracted by reflecting light to the substrate 310 by the reflective films 319. Conductive films 323 are formed in regions directly above the reflective films 319 in the insulating film 315. The conductive films 323 may be formed of an electrically conductive material, preferably a material with good adhesion to the insulating film 315, for example, Al, Ti, Cr, or ITO. A part of the conductive films 323 is in contact with the transparent electrode 314 via holes 330 provided in the insulating film 315. Although the conductive films 323 may be in contact with the transparent electrode 314 in any position, the area of the contact range is preferably as small as possible to prevent deterioration of light extraction performance due to the decrease of the areas of the reflective films 319. The conductive films 323 may be partially in contact with the reflective films 319. By providing such conductive films 323, the transparent electrode 314 and the conductive films 323 have almost the same potentials. Therefore, since the reflective films 319 are located in the same potential regions between the n-electrode 317 and the transparent electrode 314 via the insulating film 315, no electric filed is generated in the reflective films 319, thereby preventing migration.

The p-electrode 316 comprises a connecting portion 316a, a wiring portion 316b, and a contact portion 316c. The connecting portion 316a is a region which is connected to a solder layer 327. The wiring portions 316b are regions formed in a wiring pattern continuous with the connecting portion 316a. The insulating film 315 has holes 321 for passing through the insulating film 315 and exposing the transparent electrode 314, and the wiring portions 316b are also formed inside the holes 321. The contact portions 316c are circular regions provided on the transparent electrode 314. The contact portions 316c are connected to the wiring portions 316b via the holes 321.

Similar to the case of p-electrode 316, the n-electrode 317 comprises a connecting portion 317a, a wiring portion 317b, and a contact portion 317c. The contact portions 317c are circular regions provided on the n-type layer 311 exposed through the bottoms of the holes 324. The insulating film 315 has holes 320 passing through regions for filling in the holes 324, and the wiring portions 317b and the contact portions 317c are connected via the holes 320.

As shown in FIG. 10, the wiring portions 316b and 317b are respectively formed in a comb pattern, and arranged so that the teeth are engaged with each other.

The tops of the p-electrode 316 and the n-electrode 317 are covered with a protective film 322. The protective films 322 directly above the connecting portion 316a and the connecting portion 317a have respectively holes 329 and 328. The solder layer 327 directly above the protective film 322 is connected to the connecting portion 316a via the holes 329, and the solder layer 326 directly above the protective film 322 is connected to the connecting portion 317a via the holes 328.

The current blocking layers 318 are located in regions including the orthogonal projections of the contact portions 316c in plan view. The current blocking layers 318 are circles concentric with the contact portions 316c. The current blocking layers 318 are not provided in other part of the p-electrode 316 overlapping with the connecting portions 316a and the wiring portions 316b. The planar shape of the current blocking layers 318 is larger by 0 μm to 9 μm in width than that of the contact portions 316c. That is, the radius of the current blocking layer 318 is larger by 0 μm to 9 μm than that of the contact portion 316c. The side surface 318a of the current blocking layer 18 is inclined to the p-type layer 313 at an angle of 5° to 60°, thereby preventing disconnection of the p-electrode 316 or the transparent electrode 314.

Similar to the cases of the Group III nitride semiconductor light-emitting device according to Embodiments 1 and 2, the Group III nitride semiconductor light-emitting device according to Embodiment 3 also exhibits improved emission performance because the current blocking layers 318 are provided in regions including the orthogonal projections of the contact portions 316c in plan view.

### Variation

In Embodiments 1 to 3, the current blocking layer may be formed on the p-type layer so that a part of or the entire current blocking layer is enclosed with the p-type layer, and particularly so that the surface of the current blocking layer and the surface of the transparent electrode are on the same level. A difference in level (step) is not caused by provision of the current blocking layer, thereby preventing disconnection of wire or electrode. FIG. 7 shows the case when such a structure is employed in Embodiment 1. As shown in FIG. 7, the p-type layer 13 and the current blocking layers 18 are replaced with a p-type layer 413 having concave portions thereon and current blocking layers 418 for filling in the concave portions. With such a structure, the surface of the p-type layer 413 and the surfaces of the current blocking layers 418 are on the same level, and a transparent electrode 414 being formed thereon is a flat layer. In Embodiments 1 to 3, a part of or the entire current blocking layer may be enclosed with the transparent electrode.

In the Group III nitride semiconductor light-emitting devices according to Embodiments 1 to 3, the reflective films are formed in the insulating film. The reflective films may be omitted.

The Group III nitride semiconductor light-emitting device of the present invention can be employed as a light source of an illumination apparatus, or a display apparatus.

What is claimed is:

1. A Group III nitride semiconductor light-emitting device having a transparent electrode, an insulating film, and a p-electrode located in this order on a p-type layer formed of Group III nitride semiconductor, the transparent electrode being electrically connected to the p-electrode via a hole provided in the insulating film, wherein
the p-electrode comprises a connecting portion being electrically connected to the outside of the device, a wiring portion extending in a wiring pattern from the connecting portion, and a contact portion being connected to the wiring portion and being in contact with the transparent electrode via the hole;
a current blocking layer made of an insulating and transparent material with a refractive index lower than that of the p-type layer is formed between the p-type layer and the transparent electrode;
the current blocking layer is provided in a region including an orthogonal projection of the contact portion in plan view, and is not provided in a region overlapping with the wiring portion; and
the current blocking layer is larger by 0 μm to 9 μm in width than the contact portion.

2. The Group III nitride semiconductor light-emitting device according to claim 1, wherein the current blocking layer is provided only in a region including the orthogonal projection of the contact portion in plan view.

3. The Group III nitride semiconductor light-emitting device according to claim 1, wherein the current blocking layer has a thickness satisfying the relation of d>λ/(4n)(d is the thickness of the current blocking layer, n is the refractive index of the current blocking layer, and λ is the emission wavelength), and less than 1,500 nm.

4. The Group III nitride semiconductor light-emitting device according to claim 2, wherein the current blocking layer has a thickness satisfying the relation of d>λ/(4n)(d is the thickness of the current blocking layer, n is the refractive index of the current blocking layer, and λ is the emission wavelength), and less than 1,500 nm.

5. The Group III nitride semiconductor light-emitting device according to claim 1, wherein the side surface of the current blocking layer is inclined to the main surface of the p-type layer.

6. The Group III nitride semiconductor light-emitting device according to claim 2, wherein the side surface of the current blocking layer is inclined to the main surface of the p-type layer.

7. The Group III nitride semiconductor light-emitting device according to claim 3, wherein the side surface of the current blocking layer is inclined to the main surface of the p-type layer.

8. The Group III nitride semiconductor light-emitting device according to claim 1, wherein the current blocking layer has a similar planar shape as that of the contact portion.

9. The Group III nitride semiconductor light-emitting device according to claim 2, wherein the current blocking layer has a similar planar shape as that of the contact portion.

10. The Group III nitride semiconductor light-emitting device according to claim 3, wherein the current blocking layer has a similar planar shape as that of the contact portion.

11. The Group III nitride semiconductor light-emitting device according to claim 1, wherein a reflective film is formed in a region overlapping in plan view with the p-electrode of the insulating film.

12. The Group III nitride semiconductor light-emitting device according to claim 2, wherein a reflective film is formed in a region overlapping in plan view with the p-electrode of the insulating film.

13. The Group III nitride semiconductor light-emitting device according to claim 3, wherein a reflective film is formed in a region overlapping in plan view with the p-electrode of the insulating film.

14. The Group III nitride semiconductor light-emitting device according to claim 4, wherein a reflective film is formed in a region overlapping in plan view with the p-electrode of the insulating film.

15. The Group III nitride semiconductor light-emitting device according to claim 5, wherein a reflective film is formed in a region overlapping in plan view with the p-electrode of the insulating film.

16. The Group III nitride semiconductor light-emitting device according to claim 1, wherein the wiring portion is formed of high reflectance metal.

17. The Group III nitride semiconductor light-emitting device according to claim 2, wherein the wiring portion is formed of high reflectance metal.

18. The Group III nitride semiconductor light-emitting device according to claim 3, wherein the wiring portion is formed of high reflectance metal.

19. The Group III nitride semiconductor light-emitting device according to claim 4, wherein the wiring portion is formed of high reflectance metal.
